(19) United States
(12) Patent Application Publication
(10) Pub. No.: US 2026/0313837 A1
(43) Pub. Date: Oct. 8, 2026

(54) COOLING MODULE

(71) Applicant: Iceotope Group Limited, South Yorkshire (GB)

(72) Inventor: Mustafa KADHIM, South Yorkshire (GB)

(73) Assignee: Iceotope Group Limited, South Yorkshire (GB)

(21) Appl. No.: 19/479,658

(22) PCT Filed: Apr. 17, 2024
(86) PCT No.: PCT/GB2024/050998

§ 371 Date: Oct. 28, 2025

(30) Foreign Application Priority Data
Apr. 28, 2023 (GB) 2306349.8

(51) Int. Cl. H05K 7/20

(52) U.S. Cl. CPC H05K 7/20272; H05K 7/20236; H05K 7/20772

(57) ABSTRACT

A cooling module for cooling one or more electronic components within the cooling module, comprises: one or more electronic components; and a cooling element configured to cool the one or more electronic components by distributing liquid coolant over the one or more electronic components. The cooling element comprises: a first region configured to receive the liquid coolant from a supply of liquid coolant; a second region comprising a plurality of openings; and a weir between the first and second regions. The first and second regions and the weir are arranged above the one or more electronic components such that liquid coolant in the first region overflows over the weir and onto the plurality of openings, so as to distribute the liquid coolant over the one or more electronic components.

### TECHNICAL FIELD

The present disclosure concerns cooling modules for cooling electronic components using liquid coolant.

### BACKGROUND

The majority of the power supplied to information technology (IT) equipment is converted into heat within electronics components. Electronic components produce uneven amounts of heat, with some having relatively high-power profiles (e.g. central processing units (CPUs), graphics processing units (GPUs), etc.), while others have very low power profiles (such as M.2, SSDs, etc.). All electronic components can benefit from appropriate cooling, regardless of whether they have high or low power profiles.

In traditional air-cooled IT equipment, air is forced through an IT chassis enclosure where the air passes over the components and heat sinks to remove heat. In precision immersion cooling, an amount of liquid coolant for a specific component is usually chosen based on the power profile of the component. This means that the low power profile components will usually receive a small amount of liquid coolant flow.

The low power profile components may have more than a single chip that are distributed across a surface, such as a circuit board. Ideally, a flow of coolant should be distributed across all chips to avoid dry zones where the temperature of the chip may rise, which would risk the components reaching their critical limits and hence failure points. Since in conventional systems, the flow of liquid coolant does not target a single point, a sub-optimal distribution of coolant flow is an issue that is particularly pronounced when low flow rates are used.

Often, a specific back pressure is produced to provide enough flow restriction to distribute a flow of liquid coolant adequately. The back pressure can be manipulated by changing the discharge point/points sizes. The discharge points can be any form of discharge, such as holes of different shapes, slits, etc. With low flow rates, it is not possible to provide enough back pressure due to manufacturing limitations, blockage issues, unwanted surface tension effect, or forming a jet that is not suitable to cover a wider area. Supplying higher flow could improve the issue but that would mean less flow for other components and hence less effective cooling.

Therefore, there is a need to provide a more efficient and effective way of distributing liquid coolant.

WO-2022/112799 describes a heat sink arrangement for cooling first and second sets of electronic components positioned below the heat sink arrangement. This comprises: a first cooling element for cooling the first set of electronic components, wherein the first cooling element is a first heat sink comprising a base and a retaining wall that together define a volume for holding liquid coolant; and a second cooling element for cooling the second set of electronic components, configured to distribute liquid coolant over the second set of electronic components. The first and second cooling elements are arranged such that liquid coolant overflows from the volume of the first cooling element to the second cooling element for distribution over the second set of electronic components.

### SUMMARY

Against this background, the present disclosure provides a cooling module according to claim 1.

The disclosure provides a cooling module for cooling one or more electronic components, comprising: a cooling element configured to cool the one or more electronic components by distributing liquid coolant over the one or more electronic components. The cooling element comprises: a first region configured to receive the liquid coolant from a supply of liquid coolant; a second region comprising a plurality of openings; and a weir between the first and second regions. The first and second regions and the weir are positioned above the one or more electronic components such that liquid coolant in the first region overflows over the weir and onto the plurality of openings of the second region, so as to distribute the liquid coolant over the one or more electronic components.

This arrangement of the first and second regions and the weir may allow the one or more electronic components to be cooled by a relatively low-pressure flow of liquid coolant. For example, a low-pressure supply of coolant may feed the first region, which will fill with coolant. When a threshold quantity of liquid coolant is in the first region, coolant starts to overflow over the weir and fall into the second region under the influence of gravity. The falling coolant may then land on the plurality of openings and pass through the openings under the influence of gravity. This ensures that coolant is evenly distributed over the openings and therefore evenly distributed over the electronic components below.

By providing the first and second regions above the electronic components, the first and second regions do not need to be very deep. In contrast, if the first region were mounted on a circuit board adjacent the electronic components, then the first region would need to have a relatively large depth (i.e. greater than the height of the electronic components) to be able to overflow into a second region positioned above those components. Thus, the geometric arrangements of the present disclosure provide a compact and efficient way of distributing liquid coolant. The embodiments described herein can use low flow rates and low volumes of coolant to provide efficient and effective cooling.

Some embodiments of the present disclosure provide a chamber (a first region) that fills with liquid coolant and causes the liquid coolant to stabilise, before the coolant flows to another chamber (a second region). In the second region, the liquid coolant is discharged through discharge openings, which could be holes of any shape, such as a single slit, or a number of slits of any size. This can be applied in enclosed systems, such as manifolds, and in open systems, such as channelled trays.

In some embodiments relating to enclosed cooling elements, a weir within the manifold may be provided. The weir may stabilise the liquid coolant flow and distribute the fluid momentum equally across a section where the coolant will flow over the weir, to distribute coolant evenly across the discharge points. In some embodiments of open cooling elements, a stabilised section is provided, in which the coolant is first accumulated before overflowing over a weir or more to the discharge sections.

Throughout the disclosure, cooling elements for cooling electronic components are described. It will be recognised that the electronic components may be any electronic components (e.g. chips) mounted on various substrates, such as circuit boards. The surfaces on which the components are mounted are used as a reference point in the present disclosure, with the surface on which components are mounted defining an x-y plane and the vertical direction above that plane being the z-direction. Thus, when a component is described as being “above” another component, this means spaced apart in direction away from the base (x-y plane) of the cooling module, or equivalently, having a larger z-coordinate. Therefore, in embodiments of the present disclosure, the first and second regions may extend in a first direction (e.g. the x-direction) and be offset in a second direction (e.g. the y-direction direction) with the first and second regions and the weir being above the electronic components in a third direction (e.g. the z-direction).

The cooling elements described herein are preferably any element that can cool electronic components using liquid coolant. Typically, in the context of this disclosure, such cooling elements will disperse liquid coolant (e.g. dielectric liquid coolant) over electric components to transfer heat away from those components. Such distribution of liquid coolant is preferably provided by permitting the coolant to pass through the cooling elements (e.g. to drip or pour through an opening).

In this disclosure, cooling elements are described as having a first region. The first regions herein are typically the volume of the cooling element that receives coolant from a supply of liquid coolant (e.g. from a conduit carrying liquid coolant). The supply of coolant may feed coolant directly (i.e. without any intervening cooling elements, for example through a conduit) to the first region. The first regions of the present disclosure preferably hold coolant so that coolant accumulates within one or more upstanding walls before passing over a weir. The second regions also typically have one or more upstanding walls but have openings (e.g. in a base thereof) to permit coolant to leave.

The weirs described herein typically extend upward (in use) in the z-direction (i.e. away from the components requiring cooling). The effect of a weir may be that the level of liquid coolant in first region reaches a threshold height above the openings of the first region before flowing onto the openings of the second region. This may provide the advantage of increasing the pressure of coolant on the openings, improving distribution. In contrast, a slow trickle of coolant might lead to an uneven distribution over the openings.

Hence, it will be appreciated that the first regions described herein are typically upstream of the weir and downstream of a supply of coolant. The weirs are typically upstream of the second regions described herein and the second regions are typically upstream of the electronic components.

The first regions preferably comprise an inlet for receiving the liquid coolant. Such inlets may comprise a conduit (e.g. any type of tube, hose, pipe, etc.) to provide the coolant directly to the first region. Hence, fresh coolant from a heat exchanger or supply of liquid coolant may be provided. As used coolant may pool in a base of the cooling module after being distributed over electronic components, the coolant may be recycled by providing the used coolant back to the first region after passing through a heat exchanger.

It will be understood that the cooling modules described herein can be described using alternative terminology. For example, in another aspect of the present disclosure, there is provided: a cooling module for cooling one or more electronic components, comprising: one or more electronic components; and a cooling element configured to cool the one or more electronic components by distributing liquid coolant over the one or more electronic components, the cooling element comprising: a first region configured to receive the liquid coolant from a supply of liquid coolant; a second region comprising a plurality of openings; and a weir between the first and second regions; wherein the first and second regions are configured such that liquid coolant in the first region overflows over the weir and onto the plurality of openings, so as to distribute the liquid coolant over the one or more electronic components, wherein the first region is elongate (e.g. longer in the x-direction than the y-direction) and/or the second region is elongate (e.g. longer in the x-direction than the y-direction). Such an arrangement provides an efficient way of cooling electronic devices.

In a further aspect, a cooling module for cooling one or more electronic components, comprises: a first set of one or more electronic components and a second set of one or more electronic components; a first cooling element configured to cool the first set of one or more electronic components by distributing liquid coolant over the first set of one or more electronic components; a second cooling element configured to cool the second set of one or more electronic components; wherein the first cooling element comprises: a first region configured to receive the liquid coolant from a supply of liquid coolant; a second region comprising a plurality of openings; and a weir between the first and second regions; wherein the first and second regions are configured such that liquid coolant in the first region overflows over the weir and onto the plurality of openings, so as to distribute the liquid coolant over the first set of one or more electronic components; and wherein the second cooling element is configured to receive a relatively high flow rate of the liquid coolant from the supply of liquid coolant.

Embodiments of the present disclosure allow relatively low volumes of liquid coolant to be provided at low pressure to cool electronic components efficiently. The supplies of coolant do not need to provide high pressures and/or flow rates. This may be achieved by using specific geometric arrangements of chambers and weirs to allow gravity to provide adequate pressures. These and further advantages will become apparent from the disclosure.

### LISTING OF FIGURES

The disclosure may be put into practice in a number of ways and preferred embodiments will now be described by way of example only and with reference to the accompanying drawings, in which:

FIG. 1 shows a cooling module;

FIG. 2 shows a cooling element in a first embodiment, for use in the cooling module of FIG. 1; and

FIG. 3 shows a cooling element in a second embodiment, for use in the cooling module of FIG. 1.

### DETAILED DESCRIPTION

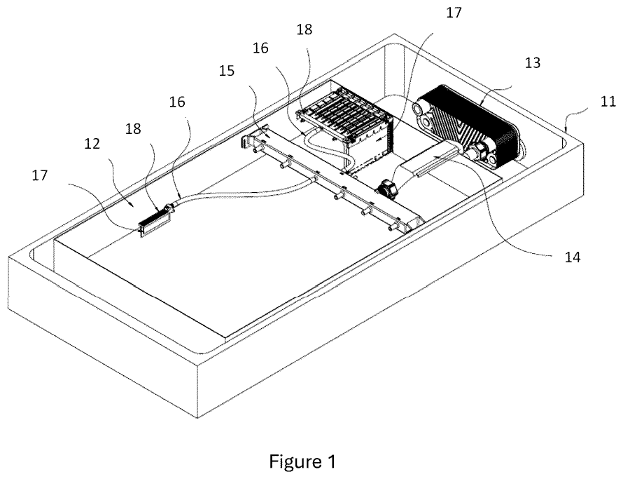

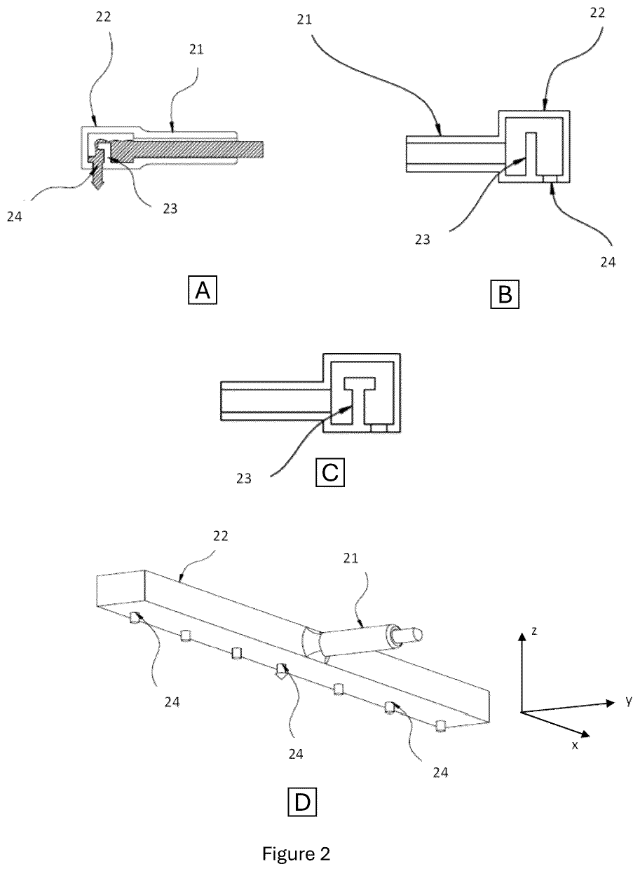

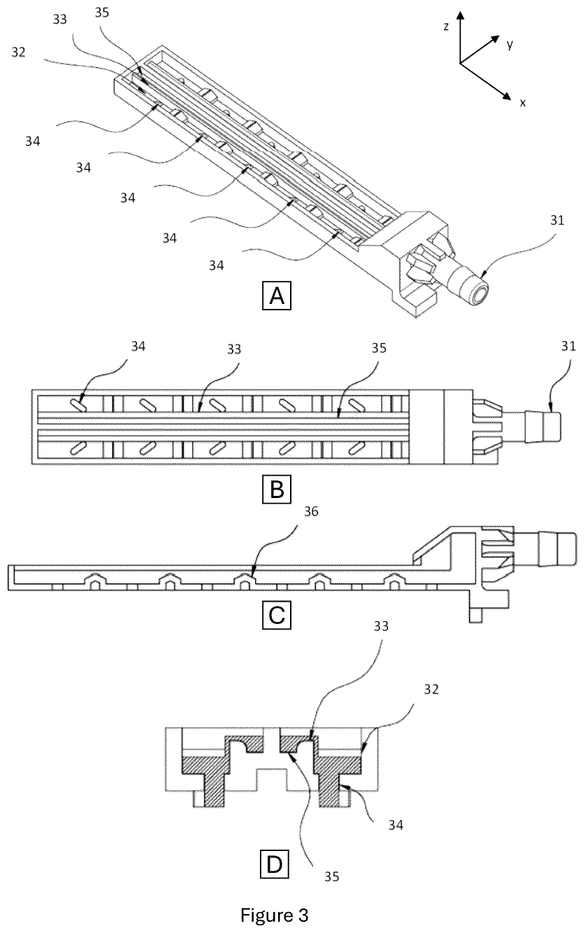

In FIG. 1, there is shown a cooling module 11 in which embodiments of the present disclosure can be implemented. Specifically, FIG. 1 shows examples of low power components 17 (SSDs and M.2) within an overall system. In this example, the cooling and IT components are contained within the cooling module 11, which is a chassis, where the liquid coolant is pumped through a heat exchanger 13 supplied to the IT components (which are part of a server 12 in this example) through a pipe 14 (or pipes) and a manifold 15 (or manifolds). The coolant is then distributed to each of the electronic components 17 that require cooling through a hose 16 (or a pipe, or any other type of conduit). Two examples of low power components 17 are shown in FIG. 1. Embodiments of the present disclosure use a cooling element 18 to cool such components 17. Embodiments of suitable cooling elements 18 are shown in FIGS. 2 and 3.

The cooling elements 18 described herein provide a first region where liquid coolant accumulates and stabilises before flowing to a second region where the coolant can be distributed over electronic components, through discharge openings. This may be applied in an enclosed cooling element, as in FIG. 2, and in an open cooling element, as in FIG. 3. In an enclosed cooling element, a weir may be provided within the manifold. The weir may stabilise the flow and distribute the fluid momentum of the liquid coolant equally across the section where the coolant flows over the weir, thereby distributing coolant evenly across discharge points. Open cooling elements may include a stabilised section where coolant is first accumulated before the coolant overflows over a weir or more to the discharge sections.

In FIG. 2, examples of enclosed manifolds are shown. FIG. 2(A) is a section view of an enclosed manifold through the inlet port showing an L-shape example of the weir. The hashed section represents the fluid volume. FIG. 2(B) is a section view of an enclosed manifold through the inlet port showing a straight weir. FIG. 2(C) is a section view of an enclosed manifold through the inlet port, showing a T-shaped weir. FIG. 2(D) is a 3D view of an example of enclosed manifold.

In the example of the enclosed manifold in FIG. 2(A), the cross-sectional view is taken through the inlet 21 from which the coolant (highlighted by the hashed section) is supplied to the manifold section 22. The coolant accumulates in the manifold section 22 in a chamber formed by the weir 23. By doing so, the coolant accumulates, stabilise, and overflow over the top of the weir 23 to the other chamber, where the coolant is discharged evenly through the holes 24.

The weir 23 effectively divides the manifold into a first region (to the right of the weir in FIG. 2(A)) and a second region (to the left of the weir in FIG. 2(A)). The weir separates the first region from the second region in the sense that fluid cannot flow from the first region to the second region without passing over the weir. In general terms, the first region is preferably a channel, such as an elongate channel. The first region is preferably longer in the x-direction than it is wide in y-direction (e.g. the length: width ratio of the first region may be at least 1:1, 2:1, or much higher). The use of a relatively narrow first region may advantageously ensure that a relatively low volume of coolant is required before coolant can flow over the weir and allows for a compact arrangement. Similarly, the second region is preferably elongate (i.e. longer in the x-direction than in the y-direction). Providing a relatively narrow second region can ensure that coolant does not need to disperse a long way in the y-direction to pass over the openings and allows for a compact arrangement.

It is advantageous for the first region to extend alongside (i.e. be directly adjacent to in the y-direction) the plurality of openings, because this can ensure that coolant falling over the weir falls directly onto (or at least close to) the openings with adequate velocity and hence pressure to cool the electronic components effectively. The first region may be at same height as the second region (i.e. the base of first region is at same height as base of second region) or may be offset in the z-direction (i.e. the base of first region is higher than the base of second region). That is, the first region may be positioned above the second region in use.

FIG. 2(A) to 2(C) each show examples of different weirs 23 having different shapes (L-shaped, straight and T-shaped) that can be used to control the follow of liquid coolant. In general terms, the weirs described herein preferably comprise a first portion extending away from the electronic components (e.g. extending vertically, or at least at a non-zero angle to the horizontal) and may also comprise a second portion (e.g. the horizontal portions of the L-shaped or T-shaped weirs) extending laterally (e.g. perpendicular to) to the first portion. The second portion of the weir may be configured to constrain the flow of liquid coolant from above and may improve the way in which the coolant flows.

FIG. 2(D) shows a three-dimensional view of the manifold, showing the inlet section 21, the manifold body 22 and the discharge sections 24 (represented by holes). The discharge sections are also referred to herein as holes and openings. It will be appreciated that any opening through which coolant may pass can serve as an appropriate opening. In general terms, each of the plurality of openings is preferably in a base (e.g. lowermost surface, in use) of the second region, which allows coolant to pass through under the influence of gravity even with low pressures from the coolant source. However, one or more openings may be in a side of the second region. The plurality of openings may be an array (e.g. an ordered, regular arrangement) of openings extending along the second region. The spacing of the openings may be chosen to correspond with the arrangement of the components to be cooled. For instance, the openings may be positioned directly above where components are expected to be positioned. The base of the first region 21 is advantageously devoid of openings (e.g. in its base), which provides a structure that allows coolant to stabilise before subsequently being distributed over the components to be cooled.

In FIG. 3, an example of an open cooling element is shown, in a further embodiment. FIG. 3(A) shows the cooling element in perspective view, FIG. 3(B) shows a top view of the cooling element, FIG. 3(C) shows a cross-section from the side, through one of the discharge chambers showing the groynes and FIG. 3(D) shows a cross-section taken along the length of the cooling element.

In use, the coolant flow enters through an inlet 31 and is then distributed into two channels 35 where the flow of liquid coolant accumulates. In this example there are two channels, but any number of such channels (i.e. more of fewer) can be provided. The coolant first loses some of its momentum as it spreads through the channels 35, before overflowing over the weir 33 and onto the discharge points 34, through which the coolant passes to cool components positioned below.

The sectional view in FIG. 3(D) shows the fluid region, which is highlighted by the hashed area. The fluid in the channel 35 overflows over the weir 33. The coolant enters the secondary chamber 32, where the flow of coolant accumulates after overflowing over the weir and is where the discharge points 34 are located. The coolant then passes through the discharge points 34 to cool components below.

In FIG. 3(D), it can be seen that each weir 33 is between a respective first region (the channels 35) and a respective second region (the secondary chambers 32). The weirs separate the first regions from the second regions in the sense that fluid cannot flow from the first regions to the second regions without passing over the weirs. Hence, in a general sense, the weirs described herein may define a wall of the first region. The weirs may provide an upstanding wall that extends in the z-direction and constrains the flow of the liquid coolant in the x-and y-directions. The weirs described herein may be extend in and/or be substantially parallel to an axis (e.g. the x-direction) of the first region and/or the second region.

Preferably, the weirs of the present disclosure extend alongside the plurality of openings of the second region. If the openings are arranged in a straight line, then the weir may be substantially parallel to the line along which the openings extend. Of course, it will be appreciated that a curved (non-linear) arrangement of openings could be provided, in which case the weir could also be curved. The distance between the openings and the weir may be constant along the length of the weir. Preferably, the weir extends alongside substantially all of the plurality of openings to ensure that all openings are provided with similar levels of coolant. However, where the cooling of certain components is less important, the distance between the weir and those less important openings may be greater than the distance between the weir and certain other openings.

As can be seen in FIGS. 2 and 3, the disclosure provides, in general terms, a weir and first regions and second regions that extend in the x-direction (a first direction). The first and/or second regions are preferably relatively narrow in the y-direction (a second direction). The cooling elements described herein can be positioned above (i.e. in the z-direction, also described herein as a third direction) electronic components that require cooling. In normal use, the z-direction is substantially parallel to the force of gravity and all directions in the present disclosure refer to the system when in use.

The cooling elements (and the constituent components, i.e. the first and second regions and weirs) can be positioned above the electronic components in various different ways. For instance, the cooling elements can be attached (e.g. by screws) to a base of the cooling module on legs that hold the cooling element above the electronic components. Alternatively, the cooling elements can be attached to (e.g. clipped to) the electronic components themselves, Alternatively, the cooling elements can be attached (e.g. by screws) to the sides of the cooling module.

As is evident from FIG. 3, it can be advantageous for the cooling elements of the present disclosure to comprise: a plurality of first regions (e.g. channels 35) and/or a plurality of second regions (e.g. chambers 32); and/or a plurality of weirs (e.g. weirs 33). The various region(s) and weir(s) could all be mutually parallel and adjacent each other. In some cases, coolant may leave a single first region by overflowing in two directions: a first direction and a second, different, direction. For example, the two first regions 35 in FIG. 3 could be combined into a single combined first region with two weirs (one weir on each long edge of the first region). In any case, at least one weir is preferably provided between every first region and a respective second region.

It will be apparent from FIG. 3 that the cooling element may not be mounted perfectly horizontally. In such a case, coolant might tend to pool at one end of the channels 35. This might cause coolant not to pass through all of the discharge points 34, leading to ineffective cooling of certain components. To accommodate for this issue, groynes 36 are provided. The groynes 36 are walls (or weirs) of any shape that form a separate chamber for the discharge sections. Effectively, the groynes 36 divide the second region into sub-regions. The sub-regions provide openings at a first height with walls dividing the openings. This can be applied advantageously in enclosed sections (e.g. manifolds) and in open sections (e.g. bathtub-style systems). In FIG. 3(C), it can be seen that the groynes 36 can help to accommodate unlevelled systems by constraining the flow of coolant in the second region in the x-direction (i.e. alongside the weir). Of course, if it is known that a cooling element is likely to be mounted horizontally then the groynes may be omitted.

In general terms, and as discussed above, the second region preferably comprises one or a plurality of groynes. These groynes may be weirs within the second region that constrain coolant to stay in certain sub-regions of the second region. This can advantageously prevent coolant accumulating unevenly in one end of the second region. Hence, the one or more groynes is preferably a plurality of groynes that are spaced apart along a length (e.g. in the x-direction) of the second region. Accordingly, the one or more groynes may extend away from the weir (i.e. the groynes may extend in the y-direction). The groynes may be substantially perpendicular to the weir. Each set of adjacent groynes preferably has at least one opening therebetween, which can ensure that an appropriate volume of coolant is provided to each opening. The plurality of openings may be in the base of the second region and at a lower height than the one or more groynes.

It will be noted that the embodiments of FIGS. 2 and 3 share a number of common features. For example, FIGS. 2 and 3 both provide a weir to stabilise and improve the flow of coolant. Moreover, both embodiments include a direct connection to a supply of coolant and both embodiments include openings in the base of the second region to permit distribution of liquid coolant. However, there are also a number of differences between the embodiments of FIGS. 2 and 3. It will be recognised that these similarities and differences between the embodiments of FIGS. 2 and 3 reflect the different cooling requirements of different arrangements of components and many different combinations of these features can be provided.

In FIG. 2, the first and second regions have a common base at the same height and the weir extends vertically from the base. In contrast, in FIG. 3, the first regions are higher than the second regions. This height difference can provide a different velocity and pressure of coolant. In FIG. 2, a single weir divides the region into just one first region and one second region. In contrast, FIG. 3 includes two weirs that provide two first regions and two second regions, and some embodiments provide more than two weirs. In FIG. 2, the cooling element is enclosed, whereas in FIG. 3 the cooling element is open.

In FIG. 2, the fluid enters through the inlet and the flow of incoming coolant is perpendicular to the weir. In contrast, in FIG. 3, the flow of incoming coolant is parallel to the weir. Hence, in some embodiments, the first regions of the present disclosure may comprise an inlet arranged such that liquid coolant enters the first region substantially parallel to the weir or substantially perpendicular to the weir. The first region may comprise an inlet. The inlet may be provided with liquid coolant by various means, such as the hose 16, or by any conduit. Fresh liquid coolant may be provided directly (i.e. without passing through other cooling elements) to the first region from a heat exchanger or a supply of liquid coolant. The inlet may be arranged such that the liquid coolant enters the first region substantially parallel to the weir (e.g. as in FIG. 3) or substantially perpendicular to the weir (e.g. as in FIG. 2), but other angles of entry may be provided.

The weirs described herein may be continuous single walls forming a chamber or they may be discontinuous, forming weir sections locally over a single discharge point or multiple discharge points. The weirs described herein can be simple straight walls or they can have other shapes such as the shapes shown in FIG. 3 (T-shape, reverse L-shape, or Y-shape of any angle). Different weir shapes can provide different flow paths and can help to stabilise the follow flow of coolant and distribute fluid momentum on a perpendicular direction of the incoming flow, as in FIG. 2, or in a direction parallel to the incoming flow, as in FIG. 3.

In embodiments of the present disclosure, there may be one or a plurality of stabilising chambers (the first regions formed by the weirs described herein), depending on the available space and the flow distribution level required. There may be one or a plurality of distinct second regions having openings therein. Additionally or alternatively, there may be a plurality of weirs in a single cooling element. The openings in the second region(s) can be individual overflow holes of different shapes or can be continuous slits (a single slit or plural slits). In general terms, the plurality of openings of the second regions described herein may comprise one or more slits and/or holes, and the dimensions (e.g. width and length) of those openings may be varied to control the flow rate. A combination of slits and/or holes can be used, and the combination can be tailored to suit specific arrangements of electronic components. The liquid coolant could be provided through a dedicated single inlet or multiple inlet nozzles or from an open bath heat sink overflow.

As mentioned previously, embodiments of the present disclosure are particularly advantageous when used with relatively low-pressure supplies of liquid coolant. Hence, in the embodiments described herein, there may be a further (i.e. a second) set of electronic components that is cooled by a second cooling element (which may be dissimilar to the cooling elements described above). The second cooling element may be provided with more coolant than the first cooling element.

In generalised terms, the one or more electronic components described herein may be a first set of one or more electronic components and the cooling element may be a first cooling element, and the cooling module may further comprise: a second set of one or more electronic components (different to the first set); and a second cooling element configured to cool the second set of one or more electronic components. The supply of liquid coolant is configured to provide liquid coolant to the first and second cooling elements. The supply of liquid coolant may be configured to provide, to the second cooling element, any one or more of: a greater volume of liquid coolant than the first cooling element; a higher flow rate of liquid coolant than the first cooling element; and a higher pressure of liquid coolant than the first cooling element. Thus, the first cooling elements described herein are particularly advantageous in such a cooling module because they are suitable for low-pressure or low flow-rate scenarios.

In the embodiments described above, the depths (as measured in the z-direction) of the first and/or second regions may be less than the height of the electronic components that are cooled.

Upon reading the embodiments described above, it will be appreciated by the skilled reader that the liquid coolant should be kept in liquid form. In other words, there should be no phase change of the liquid coolant, as evaporation of liquid coolant may reduce the efficacy of the above-described embodiments.

The various features described herein can all apply to an enclosed manifold or an open system. That is, the first and second regions may both be open or the first and second regions may both be enclosed.

It will be understood that many variations may be made to the above apparatus, systems and methods whilst retaining the advantages noted previously. For example, where specific arrangements are described, alternative arrangements can be provided that provide the same or similar functionality.

For example, the components described herein can have various dimensions. It will be understood that the present invention is not limited to cooling elements having any particular depths, lengths or heights.

The depths of the first regions described above are on the order of about 10 mm. However, various other values, such as at least 3 mm, 50 mm or 100 mm, can be used depending on flow rates, geometric constraints and other factors. The lengths of the first region can also be varied depending on the position of the component that is cooled. In the examples described above, the lengths shown are about 100 mm, although various other values, such as at least 3 mm, 50 mm or 200 mm, can be used can be used depending on flow rates, geometric constraints and other factors. The height of the weirs described above is about 5 mm. However, other heights, such as 3 mm, 10 mm, 50 mm, or 100 mm, can be used depending on flow rates, geometric constraints and other factors. The groynes described herein are shown as having a height that is slightly lower than the height of the weir. Such heights could be, for example, 1 mm, 2 mm, or 3 mm less than the height of the weir. The groynes may be 70%, 80% or 90% of the height of the weir. Again, various different heights can be used depending on flow rates and geometric constraints.

In some embodiments, the height of the weir may be slightly higher (e.g. 1 mm, 2 mm, 3 mm, etc.) than the diameter of the inlet pipe, to prevent coolant from flowing directly over the weir. Therefore, in generalised terms, the weirs described herein may be taller than the inlet(s) that provide liquid coolant to the first region. If the inlet pipe were made larger, then the weir could be made taller. The inlet may be a tube or pipe that could have any height or shape, depending on the component that is cooled or the components that the cooling element is positioned near.

The present disclosure provides cooling elements that are particularly advantageous when used with relatively low flow rates. Non-limiting examples of relatively low flow rates are between 0.05 l/min (litres per minute) and 0.25 l/min (litres per minute). However, other flow rates outside these values can be considered low flow rates. For example, any flow rate in a cooling module can be considered a “low flow rate” if the cooling module includes cooling elements that are provided with higher flow rates. Thus, while 0.05 l/min to 0.25 l/min may be described as a low flow rate in one context, these may be considered relatively high flow rates if another cooling element is provided with 0.01 l/min. Examples of relatively high flow rates (which may be used to cool high-temperature components) may be between 1.5 l/min and 3 l/min. However, it will be appreciated that the expressions “low flow rate” and “high flow rate” are not limited to these particular examples.

Advantageously, embodiments of the present disclosure may be used with pressures that are so low that the pressure is difficult to measure reliably. The weirs described herein can provide a way of providing adequate pressure in cases where back pressure cannot be used to equalise the flow on a manifold. The cooling elements described herein may be used with various flow rates (including relatively high flow rates) to improve the pressure of the coolant used to cool the electronic devices.

Moreover, various types of pumping and liquid transfer arrangements can be employed. The depicted arrangements are for illustrative purposes only and any alternative arrangement can be used, including any of the arrangements described and illustrated in WO-2019/048864 and WO-2022/112799, which are incorporated by reference. Similarly, while DIMM and M.2 have been referred to above, other electronic components can be cooled using features of the present disclosure.

It will be appreciated that the cooling elements described herein can be provided as standalone components. For example, the disclosure also provides: a cooling element configured to cool one or more electronic components by distributing liquid coolant over the one or more electronic components, the cooling element comprising: a first region configured to receive the liquid coolant from a supply of liquid coolant; a second region comprising a plurality of openings; and a weir between the first and second regions; wherein the first and second regions and the weir are configured to be positioned (e.g. configured to be mounted) above the one or more electronic components such that liquid coolant in the first region overflows over the weir and onto the plurality of openings, so as to distribute the liquid coolant over the one or more electronic components.

Additionally, the disclosure also provides: a cooling element configured to cool one or more electronic components by distributing liquid coolant over the one or more electronic components, the cooling element comprising: a first region configured to receive the liquid coolant from a supply of liquid coolant; a second region comprising a plurality of openings; and a weir between the first and second regions; wherein the first and second regions are configured such that liquid coolant in the first region overflows over the weir and onto the plurality of openings, so as to distribute the liquid coolant over the one or more electronic components. The first and/or second regions may be elongate. These regions may extend alongside the weir.

Each feature disclosed in this specification, unless stated otherwise, may be replaced by alternative features serving the same, equivalent or similar purpose. Thus, unless stated otherwise, each feature disclosed is one example only of a generic series of equivalent or similar features.

As used herein, including in the claims, unless the context indicates otherwise, singular forms of the terms herein are to be construed as including the plural form and, where the context allows, vice versa. For instance, unless the context indicates otherwise, a singular reference herein including in the claims, such as “a” or “an” (such as an electronic component or a cooling element) means “one or more” (for instance, one or more electronic components, or one or more cooling element). Throughout the description and claims of this disclosure, the words “comprise”, “including”, “having” and “contain” and variations of the words, for example “comprising” and “comprises” or similar, are not intended to (and do not) exclude other components.

The use of any and all examples, or exemplary language (“for instance”, “such as”, “for example” and like language) provided herein, is intended merely to better illustrate the disclosure and does not indicate a limitation on the scope of the disclosure unless otherwise claimed. No language in the specification should be construed as indicating any non-claimed element as essential to the practice of the disclosure.

Any steps described in this specification may be performed in any order or simultaneously unless stated or the context requires otherwise. Moreover, where a step is described as being performed after a step, this does not preclude intervening steps being performed.

All of the aspects and/or features disclosed in this specification may be combined in any combination, except combinations where at least some of such features and/or steps are mutually exclusive. In particular, the preferred features of the disclosure are applicable to all aspects and embodiments of the disclosure and may be used in any combination. Likewise, features described in non-essential combinations may be used separately (not in combination).

A method of manufacturing and/or operating any of the devices (or arrangements of devices) disclosed herein is also provided. The method may comprise steps of providing each of the features disclosed herein and/or configuring the respective feature for its stated function.

1. A cooling module for cooling one or more electronic components within the cooling module, comprising:
one or more electronic components; and
a cooling element configured to cool the one or more electronic components by distributing liquid coolant over the one or more electronic components, the cooling element comprising:
a first region configured to receive the liquid coolant from a supply of liquid coolant;
a second region comprising a plurality of openings; and
a weir between the first and second regions;
wherein the first and second regions and the weir are arranged above the one or more electronic components such that liquid coolant in the first region overflows over the weir and onto the plurality of openings, so as to distribute the liquid coolant over the one or more electronic components.

2. The cooling module of claim 1, wherein the first region comprises a channel.

3. The cooling module of claim 1, wherein the first region and the second region are elongate.

4. The cooling module of claim 1, wherein a base of the first region is devoid of openings and extends alongside the plurality of openings.

5. (canceled)

6. The cooling module of claim 1, wherein the first region is positioned above the second region.

7. (canceled)

8. The cooling module of claim 1, wherein each of the plurality of openings is in a base of the second region.

9. The cooling module of claim 1, wherein the plurality of openings is an array of openings extending along the second region.

10. The cooling module of claim 1, wherein the plurality of openings comprises one or more slits and/or holes.

11. The cooling module of claim 1, wherein the second region comprises a plurality of groynes that are spaced apart along a length of the second region and wherein at least one of the plurality of openings is between each set of adjacent groynes.

12. (canceled)

13. The cooling module of claim 11, wherein the plurality of groynes extend away from the weir.

14. (canceled)

15. The cooling module of claim 11, wherein the plurality of openings is in a base of the second region and at a lower height than the plurality of groynes.

16. The cooling module of claim 11, wherein the weir defines a wall of the first region.

17. The cooling module of claim 11, wherein the weir is substantially parallel to an axis of the first region and/or the second region.

18. The cooling module of claim 11, wherein the weir extends alongside the plurality of openings.

19. The cooling module of claim 11, wherein the weir comprises a first portion extending away from the electronic components and a second portion extending laterally to the first portion.

20. (canceled)

21. The cooling module of claim 11, wherein the cooling element comprises:
a plurality of first regions and/or a plurality of second regions; and/or
a plurality of weirs.

22. The cooling module of claim 11, wherein the cooling element comprises a plurality of first regions and a plurality of second regions, with each first region and each respective second region having a weir therebetween.

23. The cooling module of claim 11, wherein the first region comprises an inlet arranged such that the liquid coolant enters the first region substantially parallel to the weir or substantially perpendicular to the weir.

24. The cooling module of claim 11, wherein the one or more electronic components is a first set of one or more electronic components and the cooling element is a first cooling element, wherein the cooling module further comprises:
a second set of one or more electronic components; and
a second cooling element configured to cool the second set of one or more electronic components; and
the supply of liquid coolant configured to provide the liquid coolant to the first and second cooling elements.

25. The cooling module of claim 24, wherein the supply of liquid coolant is configured to provide, to the second cooling element, any one or more of:
a greater volume of liquid coolant than the first cooling element;
a higher flow rate of liquid coolant than the first cooling element; and
a higher pressure of liquid coolant than the first cooling element.
